(19) United States
(12) Patent Application Publication
(10) Pub. No.: US 2015/0198430 A1
(43) Pub. Date: Jul. 16, 2015

(54) MAGNETISM DETECTION ELEMENT AND ROTATION DETECTOR

(71) Applicant: TDK CORPORATION, Tokyo (JP)

(72) Inventors: Takahiro IMAI, Tokyo (JP); Hiraku HIRABAYASHI, Tokyo (JP)

(21) Appl. No.: 14/565,563

(22) Filed: Dec. 10, 2014

(30) Foreign Application Priority Data
Jan. 10, 2014 (JP) 2014-003262

(51) Int. Cl. G01B 7/30; G01R 33/09; G01B 7/00

(52) U.S. Cl. CPC G01B 7/30; G01B 7/003; G01R 33/09

(57) ABSTRACT

There is provided a magnetism detection element that has a compact configuration and is excellent in detection sensitivity and detection accuracy of a magnetic field. The magnetism detection element is configured to detect an external magnetic field in +X direction. The magnetism detection element includes: an MR element including a magnetization free layer and a magnetization fixed layer having a synthetic structure, the synthetic structure including a first ferromagnetic layer, a coupling layer, and a second ferromagnetic layer in order from a side close to the magnetization free layer, the first ferromagnetic layer having magnetization in the +X direction, and the second ferromagnetic layer being anti-ferromagnetically coupled with the first ferromagnetic layer through the coupling layer; and bias magnets configured to apply a bias magnetic field to the MR element in −Y direction.

### BACKGROUND

The present invention relates to a magnetism detection element detecting variation in a magnetic field, and to a rotation detection using the magnetism detection element.

Typically, a magnetism detection element is used to detect a rotation speed of a gear wheel in a non-contact manner. As such a magnetism detection element, previously, a Hall element is widely used; however, in recent years, a magneto-resistive effect element that is reduced in size and has higher sensitivity is used.

However, the magneto-resistive effect element includes a magnetic substance, and thus hysteresis is caused by behavior for an external magnetic field. In addition, in the Hall element, output is linearly varied with respect to the variation of the external magnetic field; however, the output of the magneto-resistive effect element does not show linear variation with respect to the variation of the external magnetic field.

Therefore, for example, a method in which occurrence of hysteresis is suppressed and linearity is improved by applying a bias magnetic field in a direction orthogonal to a direction of a magnetic field to be detected and saturating a free layer of the magneto-resistive effect element has been known. Note that, for example, in Japanese Unexamined Patent Application Publication No. 2001-168416, a technology relating to the method is disclosed. In Japanese Unexamined Patent Application Publication No. 2001-168416, for example, a pinned layer is magnetized in a direction orthogonal to a direction in which sensitivity of the free layer is the highest when an external magnetic field to be detected is not present in a spin valve type magneto-resistive effect element used for a thin film magnetic head, for example. This is to suppress influence of unnecessary magnetic field such as interaction magnetic field Hin on the magnetization direction of the free layer.

### SUMMARY

However, in the magneto-resistive effect element described in the above-described Japanese Unexamined Patent Application Publication No. 2001-168416, the magnetization direction of the pinned layer is different from the direction of the external magnetic field to be detected. Therefore, it is considered that the detection sensitivity to the external magnetic field may be lowered.

It is desirable to provide a magnetism detection element excellent in detection sensitivity and detection accuracy of a magnetic field, and a rotation detector using the magnetism detection element.

A magnetism detection element according to the present invention is configured to detect an external magnetic field of a first direction, and includes: a magneto-resistive effect element including a magnetization free layer and a magnetization fixed layer having a synthetic structure, the synthetic structure including a first ferromagnetic layer, a coupling layer, and a second ferromagnetic layer in order from a side close to the magnetization free layer, the first ferromagnetic layer having magnetization in the first direction, and the second ferromagnetic layer being anti-ferromagnetically coupled with the first ferromagnetic layer through the coupling layer and having magnetization in a direction different from both of the first direction and a second direction intersecting the first direction; and a bias section configured to apply a bias magnetic field to the magneto-resistive effect element in the second direction.

A rotation detector according to the present invention is provided with a gear, a first bias section configured to apply a first bias magnetic field to the gear, and a magnetism detection element configured to detect change of a component in a first direction of the first bias magnetic field associated with rotation of the gear. The magnetism detection element includes: a magneto-resistive effect element including a magnetization free layer and a magnetization fixed layer having a synthetic structure, the synthetic structure including a first ferromagnetic layer, a coupling layer, and a second ferromagnetic layer in order from a side close to the magnetization free layer, the first ferromagnetic layer having magnetization in the first direction, and the second ferromagnetic layer being anti-ferromagnetically coupled with the first ferromagnetic layer through the coupling layer and having magnetization of a direction different from both of the first direction and a second direction intersecting the first direction; and a second bias section configured to apply a second bias magnetic field to the magneto-resistive effect element in the second direction.

In the magnetism detection element and the rotation detector according to the present invention, the magnetization fixed layer of the magneto-resistive effect element has the synthetic structure, and the first ferromagnetic layer located in the vicinity of the magnetization free layer has the magnetization in the first direction same as that of the external magnetic field (or a component in the first direction of the first bias magnetic field). Therefore, variation of the output to the intensity of the external magnetic field and the like shows higher linearity, and higher output is obtainable. Here, the phrase “the first ferromagnetic layer has the magnetization in the first direction same as that of the external magnetic field and the like” means that the direction of the magnetization of the first ferromagnetic layer is substantially coincident with the direction of the external magnetic field and the like, and for example, tolerates slight deviation caused by manufacturing error or the like. In addition, high linearity is ensured by application of the bias magnetic field.

In the magnetism detection element and the rotation detector according to the present invention, the first direction and the second direction may be preferably orthogonal to each other.

The magnetism detection element according to the present invention exerts excellent detection sensitivity and excellent detection accuracy to the external magnetic field. Moreover, the rotation detector provided with the magnetism detection element according to the present invention detects the rotation angle of the gear with high accuracy.

### BRIEF DESCRIPTION OF THE DRAWINGS

FIG. 1 is a schematic diagram illustrating an entire configuration of a magnetism detection element according to a first embodiment of the invention.

FIG. 2 is a sectional diagram illustrating a structure of a main part of the magnetism detection element illustrated in FIG. 1 in an enlarged manner.

FIG. 3A is a pattern diagram for explaining a magnetization direction in a magnetization fixed layer of the magnetism detection element illustrated in FIG. 1.

FIG. 3B is another pattern diagram for explaining the magnetization direction in the magnetization fixed layer of the magnetism detection element illustrated in FIG. 1.

FIG. 4 is a characteristic diagram illustrating relationship between intensity of external magnetic field applied to an MR element and magnitude of an output (resistance) of the MR element.

FIG. 5A is a pattern diagram for explaining a magnetization direction in a magnetization fixed layer of a magnetism detection element according to a comparative example.

FIG. 5B is another pattern diagram for explaining the magnetization direction in the magnetization fixed layer of the magnetism detection element according to the comparative example.

FIG. 6 is a characteristic diagram for explaining improvement of sensitivity of the magnetism detection element illustrated in FIG. 1, with respect to the comparative example.

FIG. 7 is an explanatory diagram for explaining a procedure for determining the magnetization direction in the magnetization fixed layer of the magnetism detection element illustrated in FIG. 1.

FIG. 8 is another explanatory diagram for explaining the procedure for determining the magnetization direction in the magnetization fixed layer of the magnetism detection element illustrated in FIG. 1.

FIG. 9 is a schematic diagram illustrating an entire configuration of a rotation detector according to a second embodiment of the invention.

FIG. 10A is a first enlarged view illustrating a configuration and operation of a main part of the rotation detector illustrated in FIG. 9.

FIG. 10B is a second enlarged view illustrating the configuration and the operation of the main part of the rotation detector illustrated in FIG. 9.

FIG. 10C is a third enlarged view illustrating the configuration and the operation of the main part of the rotation detector illustrated in FIG. 9.

FIG. 10D is another enlarged view illustrating the configuration of the main part of the rotation detector illustrated in FIG. 9.

### DETAILED DESCRIPTION

Hereinafter, some embodiments of the invention will be described in detail with reference to drawings. Note that description will be given in the following order.
1. First embodiment

Magnetism detection element including magneto-resistive effect element
2. Second embodiment

Rotation detector provided with magnetism detection element

### First Embodiment

### (Configuration of Magnetism Detection Element)

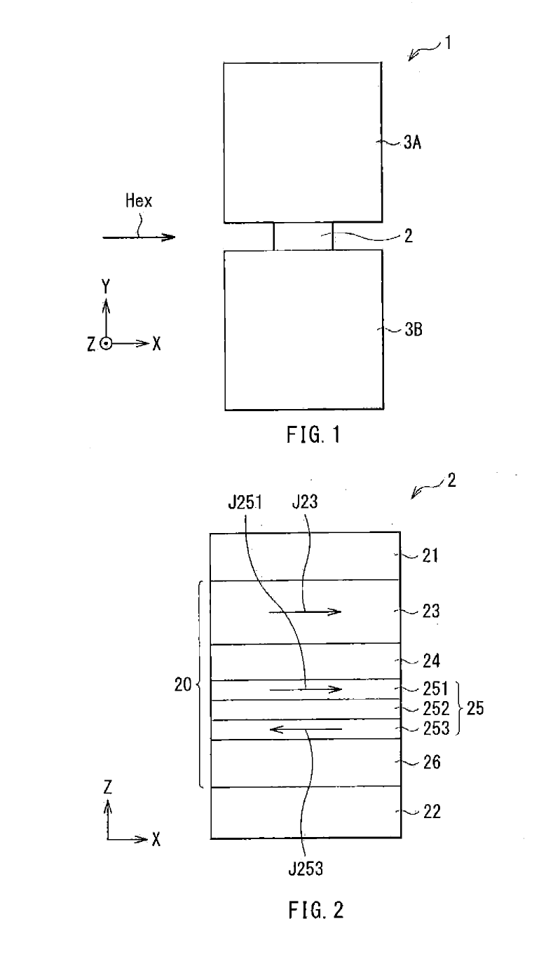

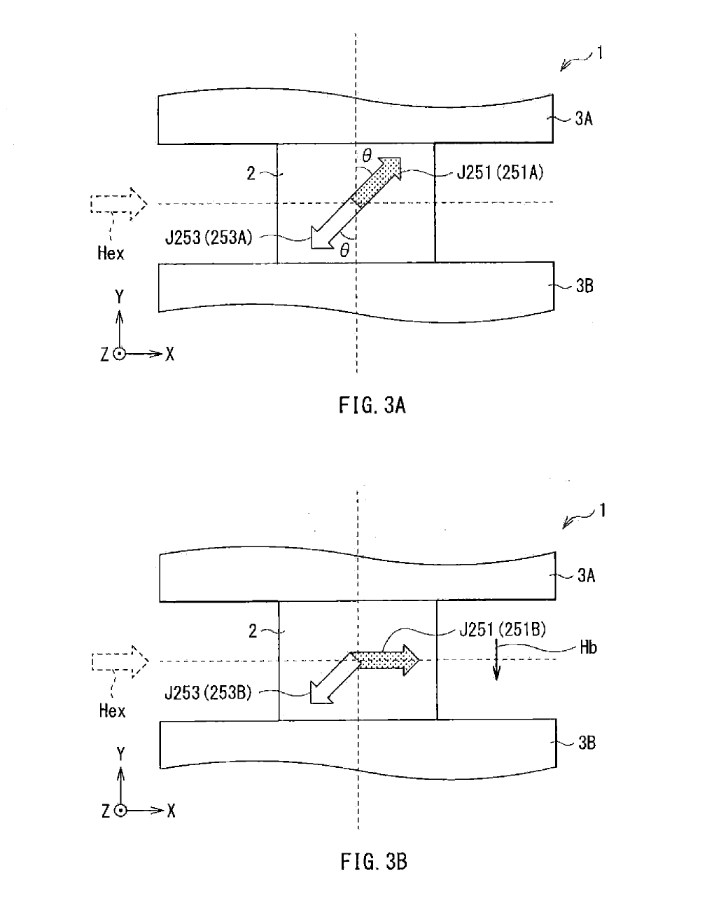

First, a configuration of a magnetism detection element 1 according to a first embodiment of the invention is described with reference to FIG. 1 and the like. FIG. 1 is a top view illustrating an entire configuration of the magnetism detection element 1. In addition, FIG. 2 is a schematic sectional view illustrating a structure of a main part of the magnetism detection element 1 in an enlarged manner. Further, FIGS. 3A and 3B are pattern diagrams each for explaining a magnetization direction of a magnetization fixed layer 25 described later.

For example, the magnetism detection element 1 may detect an external magnetic field Hex in +X direction (a first direction), and includes a magneto-resistive effect (MR) element 2 and a pair of bias magnets 3A and 3B that are oppositely disposed with the MR element 2 in between, for example, in an Y direction (a second direction). For example, the MR element 2 and the pair of bias magnets 3A and 3B may be provided commonly to a non-magnetic base substance (not illustrated), and relative positions thereof are fixed.

Each of the pair of bias magnets 3A and 3B may be a permanent magnet that applies a bias magnetic field Hb to the MR element 2 in the +Y direction. Each of the bias magnets 3A and 3B may have a thin plate shape that has a dimension in an X-axis direction (hereinafter, referred to as a length) of, for example, about 1 μm to about 100 μm, a dimension in an Y-axis direction (hereinafter, referred to as a width) of, for example, about 1 μm to about 100 μm, and a dimension in a Z-axis direction (hereinafter, referred to as a thickness) of, for example, about 10 nm to about 1 μm.

For example, as illustrated in FIG. 2, the MR element 2 includes a multilayer spin valve structure 20 stacked in the Z-axis direction perpendicular to both of the X-axis direction and the Y-axis direction, an upper electrode 21, and a lower electrode 22. The upper electrode 21 and the lower electrode 22 sandwich the multilayer spin valve structure 20 in the Z-axis direction. Specifically, the spin valve structure 20 includes a magnetization free layer 23, an interposed layer 24, a magnetization fixed layer 25, an anti-ferromagnetic layer 26 in order from the upper electrode 21 side toward the lower electrode 22 side. Incidentally, a length, a width, and a thickness of the spin valve structure 20 may be, for example, about 0.1 μm to about 10 μm, about 0.1 μm to about 10 μm, and about 10 nm to about 1 μm, respectively.

The magnetization free layer 23 is a soft ferromagnetic layer in which a direction of magnetization J23 is changed in response to the external magnetic field Hex, and for example, may have an axis of easy magnetization in the Y-axis direction. The magnetization free layer 23 may be formed of, for example, a cobalt-iron alloy (CoFe), a nickel-iron alloy (NiFe), or a cobalt-iron-boron alloy (CoFeB). Incidentally, in FIG. 2, the direction of the magnetization J23 is the +X direction; however, the direction is not fixed thereto.

The interposed layer 24 is a tunnel barrier layer that may be formed of, for example, an insulating material such as Al₂O₃ (aluminum oxide) and magnesium oxide (MgO).

The magnetization fixed layer 25 has a synthetic structure including a pinned layer 251 as a first ferromagnetic layer, a coupling layer 252, and a pinned layer 253 as a second ferromagnetic layer in order from the interposed layer 24 side. The pinned layer 251 is anti-ferromagnetically coupled with the pinned layer 253 through the coupling layer 252. Therefore, in a state where the bias magnetic field Hb is not present, namely, in a state where the pair of bias magnets 3A and 3B is not present or is not magnetized (in a demagnetization state), the direction of the magnetization J251 of the pinned layer 251 is opposite to the direction of the magnetization J253 of the pinned layer 253 (see FIG. 3A). Here, the magnetization J251 and the magnetization J253 face in a direction different from both of the X-axis direction and the Y-axis direction in a plane (in an XY plane) orthogonal to the Z-axis. Specifically, for example, the direction of the magnetization J251 and the direction of the magnetization J253 may be fixed in a state inclined by an angle θ with respect to the Y-axis. For convenience, the directions of the magnetization J251 and J253 in the demagnetization state are denoted by 251A and 253A, respectively. Note that FIG. 2 illustrates that the directions of the magnetization J251 and the magnetization J253 are fixed in the XY plane, and does not illustrate that the directions of the magnetization J251 and the magnetization J253 are fixed to the +X direction and the −X direction, respectively.

On the other hand, in a state where the bias magnetic field Hb in the −Y direction is applied to the magnetization fixed layer 25 by the pair of magnetized bias magnets 3A and 3B (in a magnetization state), the direction of the magnetization J251 of the pinned layer 251 is not anti-parallel to the direction of the magnetization J253 of the pinned layer 253 (see FIG. 3B). This is because the directions of the magnetization J251 and the magnetization J253 are inclined by influence of the bias magnetic field Hb. At this time, the magnetization J251 may be preferably fixed along the +X direction, for example. The directions of the magnetization J251 and J253 in the magnetization state are denoted by 251B and 253B, respectively, for convenience. Incidentally, it is assumed that the directions of the magnetization J251 and J253 are not changed by the external magnetic field Hex to be detected. This is because the external magnetic field Hex having large intensity that influences the directions of the magnetization J251 and J253 is virtually difficult to be detected accurately.

Each of the pinned layers 251 and 253 is formed of a ferromagnetic material such as cobalt (Co), CoFe, and CoFeB, and the coupling layer 252 is formed of a nonmagnetic high-conductive material such as ruthenium (Ru). Each of the pinned layers 251 and 253 may have a single layer structure or a multilayer structure configured of a plurality of layers.

The anti-ferromagnetic layer 26 is formed of an anti-ferromagnetic material such as a platinum-manganese alloy (PtMg) and an iridium-manganese alloy (IrMn). The anti-ferromagnetic layer 26 functions to fix the direction of the magnetization J253 of the adjacent pinned layer 253 to one direction.

Each of the upper electrode 21 and the lower electrode 23 may be formed of, for example, a nonmagnetic high-conductive material such as copper (Cu). The upper electrode 21 and the lower electrode 22 are each connected to a conductive wire (not illustrated), and for example, a current may flow in a direction from the upper electrode 21 toward the lower electrode 22 (in the −Z direction).

### (Function of Magnetism Detection Element)

The magnetism detection element 1 of the first embodiment detects the external magnetic field Hex in a state where the pair of bias magnets 3A and 3B is magnetized, namely, in a state where the bias magnetic field Hb is applied to the MR element 2. Here, the magnetization fixed layer 25 of the MR element 2 has the synthetic structure, and the pinned layer 251 located in the vicinity of the magnetization free layer 23 has the magnetization J251 along the external magnetic field Hex. Therefore, as compared with the case where the magnetization J251 is largely deviated from the direction of the external magnetic field Hex, the variation of the output with respect to the intensity of the external magnetic field Hex shows higher linearity and higher output is obtainable.

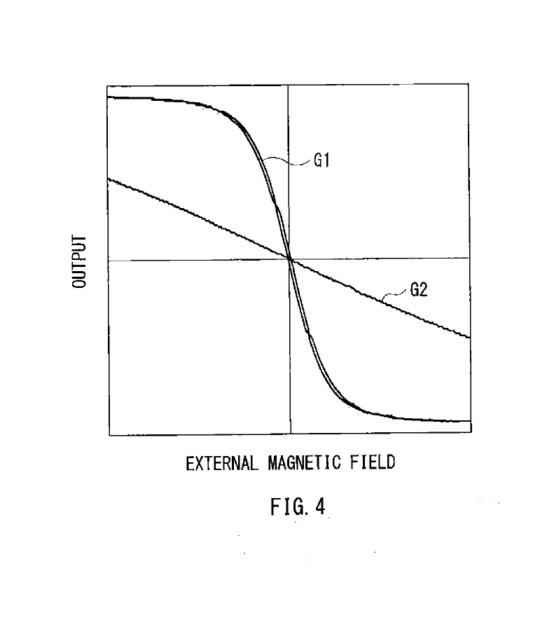

Typically, relationship between the intensity of the external magnetic field applied to the MR element and the magnitude of the output (resistance) of the MR element may be represented by a curved line like a graph G1 illustrated in FIG. 4, for example. However, the MR element used for the magnetism detection element detecting variation of the external magnetic field may desirably have output variation (resistance change) close to a straight line like a graph G2 illustrated in FIG. 4, with respect to the intensity of the external magnetic field. Such high linearity is obtained by applying a bias magnetic field having higher intensity to the MR element.

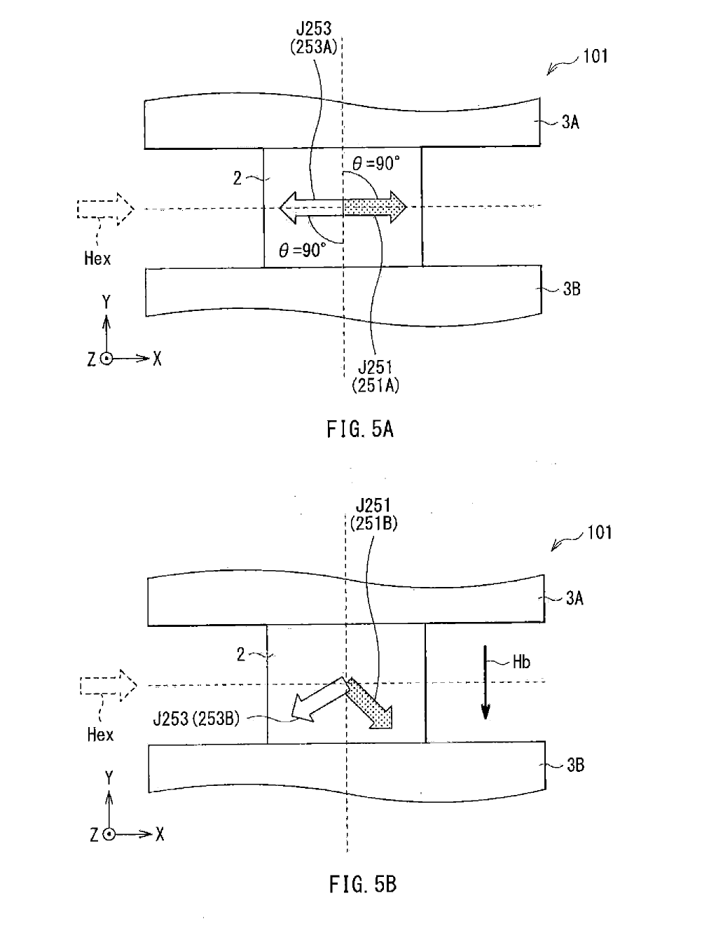

However, application of the bias magnetic field having such higher intensity degrades sensitivity of the MR element. This is because rotation of the magnetization of the magnetization free layer is suppressed by strong magnetic field. Further, the bias magnetic field having higher intensity also changes the direction of the magnetization of the magnetization fixed layer that is essentially difficult to be affected by the external magnetic field. For example, as illustrated in FIG. 5A, it is assumed that the direction of the magnetization J251 is made coincident with the direction of the external magnetic field Hex in the state where the bias magnets 3A and 3B are not magnetized (in the demagnetization state). In this case, for example, as illustrated in FIG. 5B, the direction of the magnetization J251 of the pinned layer 251 is largely different from the direction of the external magnetic field Hex, depending on the intensity of the bias magnetic field Hb.

Therefore, in the first embodiment, the direction of the magnetization J251 is made coincident with the direction of the external magnetic field Hex in a state where the bias magnetic field Hb is applied (in the magnetization state). Thus, when the external magnetic field Hex is zero (Hex=0), the direction of the magnetization J23 of the magnetization free layer 23 is coincident with the direction of the bias magnetic field Hb. Therefore, the direction of the magnetization J23 is substantially orthogonal to the direction of the magnetization J251. As a result, the MR element 2 is allowed to detect the variation of the external magnetic field Hex in a region where the output variation with respect to the external magnetic field Hex shows higher linearity. In other words, sensitivity of the magnetism detection element 1 is improved.

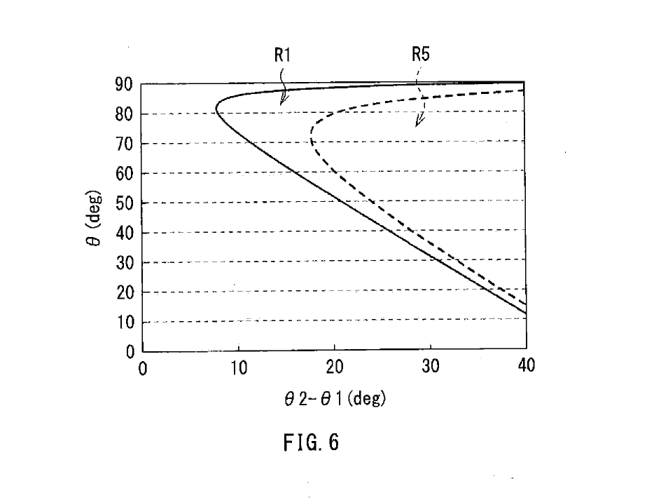

Here, in the case where the following expression (1) is satisfied, the sensitivity of the magnetism detection element 1 of the first embodiment is expected to be improved by n % or more with reference to the sensitivity of a magnetism detection element 101 of a comparative example. FIG. 6 illustrates a region R1 where sensitivity is expected to be improved by about 1% or more and a region R5 where the sensitivity is expected to be improved by about 5% or more in relation between angle difference θ2−θ1 and an angle θ. In FIG. 6, a region where the angle difference θ2−θ1 is larger than a solid line is the region R1, and a region where the angle difference θ2−θ1 is larger than a dashed line is the region R5.

sin θ+cos θ×tan(θ2−θ1)≧1+0.01×n (1)

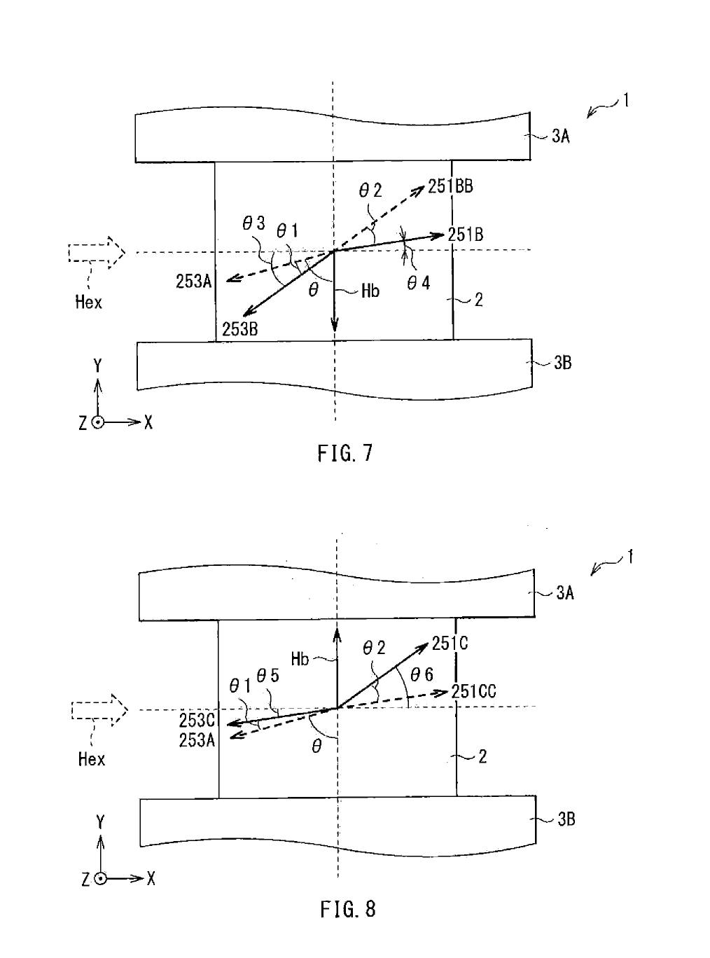

In the expression (1), the angle θ is an angle formed by the direction 253A of the magnetization J253 in the demagnetization state and the direction of the bias magnetic field Hb to be applied thereafter. Moreover, the angle θ1 is an angle formed by the direction 253A of the magnetization J253 in the demagnetization state and the direction 253B of the magnetization J253 in the magnetization state. Further, the angle θ2 is an angle that is formed by a direction 251BB of the magnetization J251 when being free from influence of the bias magnetic field Hb and the direction 251B of the magnetization J251 in the magnetization state (see FIG. 7). Note that the direction 251BB of the magnetization J251 is a direction opposite to the direction 253B of the magnetization J253 in the magnetization state (a direction inverted by 180 degrees).

Incidentally, the angle of the difference (θ2−θ1) between the angle θ2 and the angle θ1 is allowed to be obtained in the following manner. First, normal sensitivity S1 in a state where the bias magnetic field Hb in the −Y direction is applied to the MR element 2 is determined (see FIG. 7). The sensitivity S1 is represented by the following expression with use of an angle θ4 illustrated in FIG. 7 and the like.

$$\begin{matrix}S 1 ∝ cos ( θ 4 ) \\ = cos ( θ 3 - θ 2 ) \\ = cos [ ( π / 2 - θ + θ 1 ) - θ 2 ] \\ = cos [ π / 2 - θ - ( θ 2 - θ 1 ) ]\end{matrix} \qquad ( 2 )$$

Next, demagnetization of the pair of bias magnets 3A and 3B is performed to determine the angle θ.

After that, for example, as illustrated in FIG. 8, the bias magnets 3A and 3B are magnetized in the +Y direction that is opposite to the normal direction, and the bias magnetic field Hb in the +Y direction is applied to the MR element 2. Here, the angle θ1 is an angle formed by the direction 253A of the magnetization J253 in the demagnetization state and a direction 253C of the magnetization J253 in the magnetization state. Further, the angle θ2 is an angle that is formed by a direction 251CC of the magnetization J251 when being free from influence of the bias magnetic field Hb and a direction 251C of the magnetization J251 in the magnetization state (see FIG. 8). Note that the direction 251CC of the magnetization J251 is a direction opposite to the direction 253C of the magnetization J253 in the magnetization state (a direction inverted by 180 degrees).

In this state, when the sensitivity S2 is determined, the sensitivity S2 is represented by the following expression with use of an angle θ6 illustrated in FIG. 8.

$$\begin{matrix}S 2 ∝ cos ( θ 6 ) \\ = cos ( θ 5 + θ 2 ) \\ = cos [ ( π / 2 - θ1 - θ ) + θ 2 ] \\ = cos [ π / 2 - θ + ( θ 2 - θ 1 ) ]\end{matrix} \qquad ( 3 )$$

Here, when S3=tan(π/2−θ) is established, the following expression is obtained from the above-described expressions (2) and (3).

tan(θ2−θ1)=(S1−S2)/[S3×(S1+S2)] (4)

Since the angle θ is already known, the angle difference θ2−θ1 is determined from the expression (4). Here, the angle difference θ2−θ1 may be desirably equal to or larger than 8 degrees (θ2−θ1≧8°). This is because improvement of the sensitivity of about 1% or more is expected as illustrated in FIG. 6.

### (Effects of Magnetism Detection Element)

In this way, according to the magnetism detection element 1 of the first embodiment, it is possible to exert excellent detection sensitivity and excellent detection accuracy to the external magnetic field Hex without enlarging the dimensions thereof.

### Second Embodiment

### (Configuration of Rotation Detector)

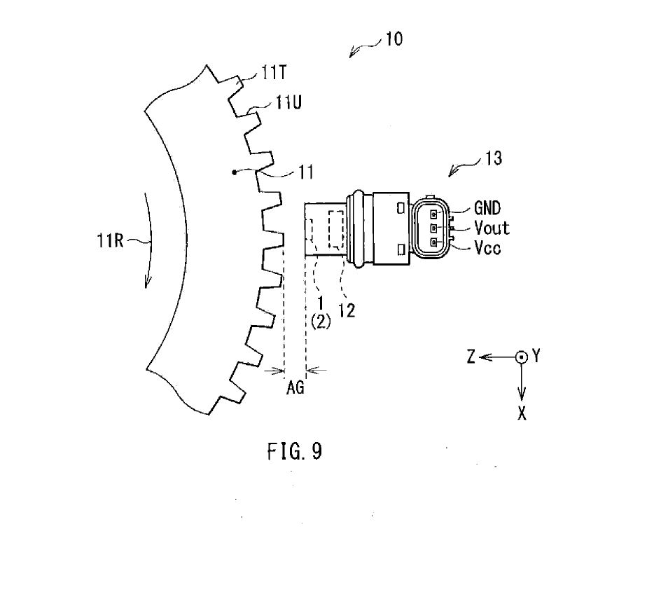

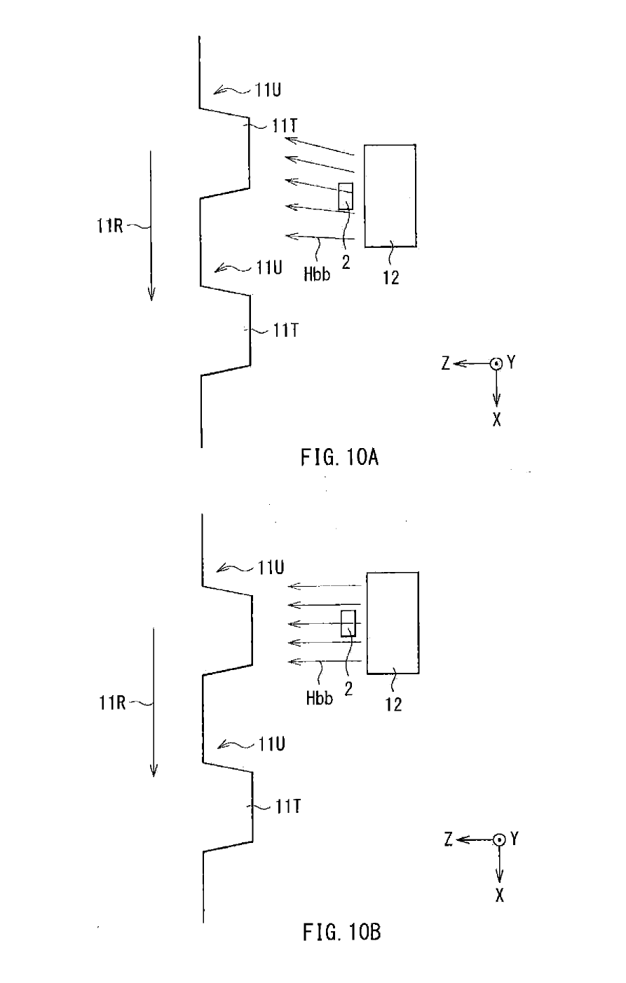

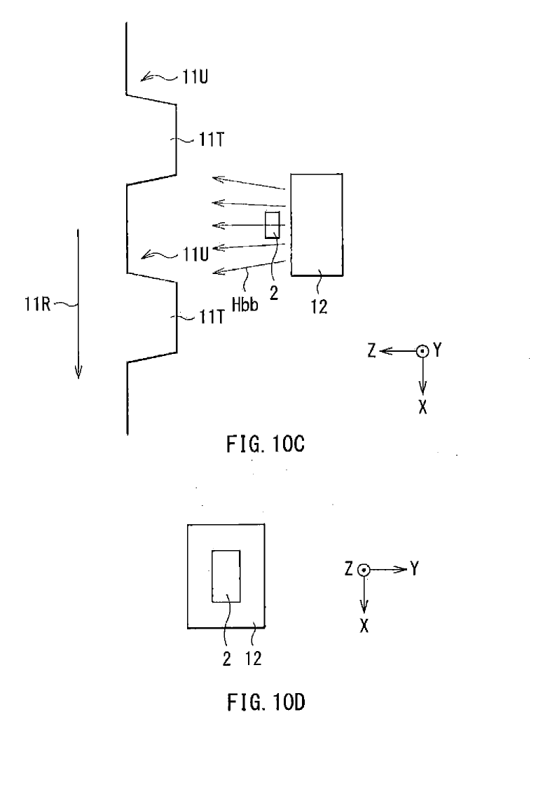

Subsequently, a configuration of a rotation detector 10 according to a second embodiment of the invention is described with reference to FIG. 9 and the like. FIG. 9 is a schematic diagram illustrating an entire configuration of the rotation detector 10 as viewed from a side direction. In addition, FIGS. 10A to 10C are enlarged views each illustrating arrangement position and dimension ratio of main components of the rotation detector 10 and operation of the rotation detector 10.

The rotation detector 10 includes the magnetism detection element 1 described in the above-described first embodiment, and is a so-called gear tooth sensor or gear sensor. The rotation detector 10 includes a gear 11 and a detection section 13 that is disposed oppositely to the gear 11 and includes the magnetism detection element 1 and a magnet 12 therein. The rotation detector 10 determines a rotation speed and a rotation angle of the gear 11 with use of the magnetism detection element 1. The magnet 12 is located on a side opposite to the gear 11 with the magnetism detection element 1 in between. Here, in the magnetism detection element 1, the bias magnets 3A and 3B apply the bias magnetic field Hb in the +Y direction to the MR element 2. On the other hand, the magnet 12 applies a back bias magnetic field Hbb (see FIGS. 10A to 10C) in a third direction (the +Z direction) to the gear 11 and the magnetism detection element 1. The magnetism detection element 1 detects variation of the back bias magnetic field Hbb (variation of the X-axis component) with use of the MR element 2. Further, FIG. 10D illustrates positional relationship between the MR element 2 and the magnet 12 as viewed from the gear 11. As illustrated in FIGS. 10A to 10D, the magnet 12 is sufficiently larger than the MR element 2 in size. For example, the MR element 2 may have a length (a dimension in the X-axis direction) of about 1 mm, a width (a dimension in the Y-axis direction) of about 0.4 mm, and a thickness (a dimension in the Z-axis direction) of about 0.4 mm. On the other hand, for example, the magnet 12 may have a length of about 4 mm, a width of about 3 mm, and a thickness of about 2 mm.

The gear 11 has convex sections 11 and concave sections 11U that are each formed of a magnetic substance and are alternately arranged at a pitch of, for example, about 2 to 7 mm in a circular peripheral region. The gear 11 rotates in a direction of an allow 11R. The convex section 11 and the concave section 11U are alternately located at a position closest to the MR element 2 of the detection section 13 by the rotation operation of the gear 11. A distance AG between a top part of the convex section 11T and the MR element 2 may be, for example, about 0.5 mm or more and 3 mm or less.

### (Operation of Rotation Detector)

In the rotation detector 10, for example, when the gear 11 rotates from a state of FIG. 10A in a direction of the allow 11R, the convex section 11T and the concave section 11U of the gear 11 alternately face the MR element 2 of the detection section 13. At this time, for example, when the convex section 11T formed of a magnetic substance comes close to the MR element 2 as illustrated in FIG. 10B, a magnetic flux of the back bias magnetic field Hbb from the magnet 12 located behind the MR element 2 concentrates on the convex section 11T. In other words, since spread of the magnetic flux in the X-axis direction is small, the X-axis component of the back bias magnetic field Hbb is relatively small. On the other hand, for example, when the convex section 11T gets away from the MR element 2 and the concave section 11U comes close to the MR element 2 as illustrated in FIG. 10C, a part of the magnetic flux of the back bias magnetic field Hbb heads toward the convex sections 11T that are locate on both sides of the concave section 11U. In other words, since the spread of the magnetic flux in the X-axis direction increases, the X-axis component of the back bias magnetic field Hbb relatively increases. The direction of the magnetization J23 of the magnetization free layer 23 in the MR element 2 changes in response to the change of the X-axis component of the back bias magnetic field Hbb. It is possible to detect the rotation angle and the rotation speed of the gear 11 with use of the resistance change of the MR element 2 associated with the change. Note that, as illustrated in FIG. 9, the detection section 13 is provided with a power terminal Vcc for supplying a power voltage to the MR element 2, a ground terminal GND, and an output terminal Vout for extracting output from the MR element 2.

### (Effects of Rotation Detector)

As described above, since the rotation detector 10 according to the second embodiment includes the magnetism detection element 1, it is possible to detect the rotation angle and the rotation speed of the gear 11 with high accuracy while downsizing the entire configuration.

As described above, the present invention has been described with reference to some embodiments. However, the present invention is not limited to the embodiments, and various modifications may be made. For example, in the above-described embodiments, the tunnel MR element has been described as an example of the MR element. However, the present invention is not limited thereto, and for example, a CPP-type GMR element may be employed. In this case, it is sufficient to form the interposed layer as a non-magnetic conductive layer made of nonmagnetic high-conductive material such as gold (Au), silver (Ag), and copper (Cu).

Moreover, in the above-described second embodiment, the case where the magnetism detection element is applied to the rotation detector such as a gear tooth sensor has been described as an example. However, the present invention is not limited thereto. For example, the magnetism detection element of the present invention may be applied to other sensors such as an open-type current sensor. Such a current sensor detects a magnetic field that is generated by a current flowing through a conductor, to measure a value of the current. It is possible to measure the current value more accurately by using the magnetism detection element of the present invention.

What is claimed is:

1. A magnetism detection element configured to detect an external magnetic field in a first direction, the magnetism detection element comprising:
a magneto-resistive effect element including a magnetization free layer and a magnetization fixed layer having a synthetic structure, the synthetic structure including a first ferromagnetic layer, a coupling layer, and a second ferromagnetic layer in order from a side close to the magnetization free layer, the first ferromagnetic layer having magnetization in the first direction, and the second ferromagnetic layer being anti-ferromagnetically coupled with the first ferromagnetic layer through the coupling layer and having magnetization in a direction different from both of the first direction and a second direction intersecting the first direction; and
a bias section configured to apply a bias magnetic field to the magneto-resistive effect element in the second direction.

2. The magnetism detection element according to claim 1, wherein the first direction is orthogonal to the second direction.

3. The magnetism detection element according to claim 1, wherein magnetization of the second ferromagnetic layer has a vector component in the second direction.

4. The magnetism detection element according to claim 2, wherein magnetization of the second ferromagnetic layer has a vector component in the second direction.

5. A rotation detector provided with a gear, a first bias section configured to apply a first bias magnetic field to the gear, and a magnetism detection element configured to detect change of a component in a first direction of the first bias magnetic field associated with rotation of the gear, the magnetism detection element comprising:
a magneto-resistive effect element including a magnetization free layer and a magnetization fixed layer having a synthetic structure, the synthetic structure including a first ferromagnetic layer, a coupling layer, and a second ferromagnetic layer in order from a side close to the magnetization free layer, the first ferromagnetic layer having magnetization in the first direction, and the second ferromagnetic layer being anti-ferromagnetically coupled with the first ferromagnetic layer through the coupling layer and having magnetization of a direction different from both of the first direction and a second direction intersecting the first direction; and
a second bias section configured to apply a second bias magnetic field to the magneto-resistive effect element in the second direction.
